(19) United States
(12) Patent Application Publication
(10) Pub. No.: US 2020/0035713 A1
(43) Pub. Date: Jan. 30, 2020

(54) Array substrate and method of manufacturing the same, display panel and display apparatus

(71) Applicants: Ordos Yuansheng Optoelectronics Co., Ltd., Inner Mongolia (CN); BOE TECHNOLOGY GROUP CO., LTD., Beijing (CN)

(72) Inventors: Liman Peng, Beijing (CN); Qi Liu, Beijing (CN); Hengbo Liu, Beijing (CN); Jin Yang, Beijing (CN); Yan Wu, Beijing (CN); Zihua Li, Beijing (CN); Qianqian Zhang, Beijing (CN); Yi Wang, Beijing (CN); Guoping Zhang, Beijing (CN); Haifeng Xu, Beijing (CN); Wenxiu Li, Beijing (CN); Lei Wang, Beijing (CN); Zhilong Chen, Beijing (CN); Zhiyong Xue, Beijing (CN); Jianqiang Wang, Beijing (CN)

(73) Assignees: Ordos Yuansheng Optoelectronics Co., Ltd., Inner Mongolia (CN); BOE TECHNOLOGY GROUP CO., LTD., Beijing (CN)

(21) Appl. No.: 16/390,445

(22) Filed: Apr. 22, 2019

(30) Foreign Application Priority Data
Jul. 26, 2018 (CN) 201821196232.9

(51) Int. Cl. H01L 27/12

(52) U.S. Cl. CPC H01L 27/1218; H01L 27/1262; H01L 27/1244

(57) ABSTRACT

Embodiments of the present disclosure provide an array substrate and a manufacturing method thereof, a display panel, and a display apparatus. The array substrate includes: a base substrate; a first conductive layer on a side of the base substrate; the first insulating layer on a side of the first conductive layer away from the base substrate; and a second conductive layer on a side of the first insulating layer away from the first conductive layer. The array substrate includes a pixel region and a signal input region, and a portion of the first insulating layer in the pixel region has a thickness less than that of a portion of the first insulating layer in the signal input region.

### CROSS-REFERENCE TO RELATED APPLICATION

This application claims the benefit of Chinese Patent Application No. 201821196232.9, entitled “array substrate, display panel, and display apparatus”, filed with the State Intellectual Property Office of China on Jul. 26, 2018, the whole disclosure of which is incorporated herein by reference.

### TECHNICAL FIELD

Embodiments of the present disclosure relate to the field of display technologies, and in particular, to an array substrate and a manufacturing method thereof, a display panel, and a display apparatus.

### DESCRIPTION OF RELATED ART

With the rapid development of display technology, active organic light-emitting diode (AMOLED) display devices have become one of the main types display in the display apparatus market, and AMOLED display devices have wider viewing angles, greater refresh rates, and thinner sizes to meet the needs of the vast number of consumers. Therefore, there is requirement to further improve the performance, for example, reliability, of an AMOLED display apparatus.

### SUMMARY

Embodiments of the present disclosure provide an array substrate and a method of manufacturing the same, a display panel and a display apparatus, which may at least alleviate short circuit between stacked lines in the array substrate.

As an aspect, there is provided an array substrate, including:

a base substrate;

a first conductive layer on a side of the base substrate;

a first insulating layer on a side of the first conductive layer facing away from the base substrate; and

a second conductive layer on a side of the first insulating layer facing away from the first conductive layer;

wherein, the base substrate includes a pixel region and a signal input region, and a thickness of a portion of the first insulating layer in the pixel region is less than a thickness of a portion of the first insulating layer in the signal input region.

In an embodiment, the array substrate further includes an active layer on a side of the first conductive layer facing away from the first insulating layer.

In an embodiment, the array substrate further includes a second insulating layer on a side of the active layer facing the first conductive layer.

In an embodiment, the array substrate further includes a buffer layer on a side of the active layer facing away from the first conductive layer.

In an embodiment, the array substrate further includes a planarization layer on a side of the second conductive layer facing away from the first conductive layer, the planarization layer covering the second conductive layer.

In an embodiment, the portion of the first insulating layer in the pixel region has a thickness in a range of 1000 angstroms ˜2500 angstroms or less than 1000 angstroms.

In an embodiment, the portion of the first insulating layer in the signal input region has a thickness in a range of 3000 angstroms ˜8000 angstroms or greater than 8000 angstroms.

In an embodiment, the first insulating layer is made of silicon oxide.

In an embodiment, the second insulating layer is made of silicon dioxide or silicon nitride.

As an aspect, there is provided a display panel including the array substrate as mentioned above.

As an aspect, there is provided a display apparatus including the array substrate as mentioned above.

As an aspect, there is provided a method of manufacturing an array substrate, the method including:

providing a first conductive layer on a side of a base substrate, the base substrate including a pixel region and a signal input region;

forming a first insulating layer with a first predetermined thickness on a side of the first conductive layer facing away from the base substrate;

forming a photoresist layer on a side of the first insulating layer facing away from the first conductive layer, and performing exposure and development processes on the photoresist layer to remove the photoresist layer in the pixel region of the base substrate; and

etching the first insulating layer in the pixel region of the base substrate such that a thickness of a portion of the first insulating layer in the pixel region of the base substrate is reduced from the first predetermined thickness to the second predetermined thickness.

In an embodiment, the method further includes:

peeling off the photoresist layer in the signal input region and simultaneously forming a second conductive layer on the portion of the first insulating layer having the first predetermined thickness in the signal input region and the portion of the first insulating layer having the second predetermined thickness in the pixel region.

In an embodiment, the method further includes:

before providing the first conductive layer on the side of the base substrate, providing an active layer over the base substrate in the pixel region.

In an embodiment, the method further includes: before providing the first conductive layer on the side of the base substrate and after providing the active layer over the base substrate in the pixel region, providing a second insulating layer on a side of the active layer facing the first conductive layer.

In an embodiment, the method further includes: before providing the active layer over the base substrate in the pixel region, providing a buffer layer on the base substrate.

In an embodiment, the method further includes: providing a planarization layer on a side of the second conductive layer facing away from the base substrate.

In an embodiment, the first insulating layer is made of silicon oxide.

In an embodiment, the second insulating layer is made of silicon dioxide or silicon nitride.

### BRIEF DESCRIPTION OF THE DRAWINGS

FIG. 1 is a structural schematic view of an array substrate according to embodiments of the present disclosure;

FIG. 2 is a structural schematic view of an array substrate according to embodiments of the present disclosure during manufacturing;

FIG. 3 is a structural schematic view of an array substrate according to embodiments of the present disclosure during manufacturing;

FIG. 4 is a structural schematic view of an array substrate according to embodiments of the present disclosure during manufacturing;

FIG. 5 is a structural schematic view of an array substrate according to embodiments of the present disclosure during manufacturing; and

FIG. 6 is a structural schematic view of an array substrate according to embodiments of the present disclosure during manufacturing.

### DETAILED DESCRIPTION

In order to further explain the technical means and functions of the present disclosure for achieving the intended purpose of the disclosure, the specific embodiments, structures, features and functions of the array substrate according to the present disclosure will be described in detail below with reference to the accompanying drawings. The description is as follows.

An active organic light-emitting diode (AMOLED) display apparatus in the related art is configured to be driven by using a current, which makes a drive circuit in the AMOLED display panel be complicated, and a plurality of circuit lines be formed on the panel. In this case, insulating layers are arranged between the stacked circuit lines so as to avoid short circuit between the circuit lines. However, when the voltages of the circuit lines are too large, the insulation layer may be broken down at an overlapping part of the circuit lines, causing short circuit phenomenon and thus damaging the display.

As shown in FIG. 1, embodiments of the present disclosure provide an array substrate, including:

a base substrate 7, the base substrate 7 including a pixel region and a signal input region, in other words, the base substrate 7 may be divided into the pixel region and the signal input region, or after the array substrate is formed, the pixel region of the base substrate 7 is a pixel region of the array substrate, and the signal input region of the base substrate 7 is a signal input region of the array substrate; a first conductive layer 1 located at a side of the base substrate; a first insulating layer 2 located at a side of the first conductive layer 1 facing away from the base substrate; and a second conductive layer on a side of the first insulating layer facing away from the first conductive layer. The first conductive layer and the second conductive layer may be formed from a metal layer.

According to the embodiment, a thickness of a portion of the first insulating layer 2 in the pixel region is less than a thickness of a portion of the first insulating layer 2 in the signal input region.

Embodiments of the present disclosure provide an array substrate that may reduce a short circuit between stacked circuit lines in an array substrate. In the related art, a line voltage in a signal input region is greater than that in a pixel region of the array substrate. When the array substrate is subjected to a TFT aging test, the first insulating layer between the first conductive layer and the second conductive layer is often broken down in the signal input region, resulting in a short circuit between the first conductive layer and the second conductive layer and thus affecting the quality of the array substrate. Compared with the related art, in the array substrate provided by the embodiments of the present disclosure, the thickness of the portion of the first insulating layer in the pixel region is less than the thickness of the portion of the first insulating layer in the signal input region. In this way, the thickness of the portion of the first insulating layer in the signal input region can be increased without affecting the thickness of the portion of the first insulating layer in the pixel region, thereby ensuring the display effect of the pixel region while avoiding breakdown of the first insulating layer and short circuit between the first conductive layer and the second conductive layer in the signal input region.

According to embodiments of the present disclosure, the array substrate is mainly applied to an AMOLED display panel, and the light-emitting principle of the AMOLED display panel is performed by applying electrical current between a cathode layer and an anode layer in the display panel such that an organic functional layer between the cathode layer and the anode layer emits light to realize display of an image. The array substrate provided in the embodiment may be used as the cathode layer or the anode layer of the display panel. In one embodiment, the array substrate is used as an anode layer of a display panel.

In the embodiment, the array substrate includes a pixel region and a signal input region, wherein the pixel region substantially corresponds to the display area in the display panel, and is mainly used to control a luminance of the pixel unit or color of the light to realize the display of the image. The signal input region mainly includes some input signal lines of driving circuits for signal input, for example, V_{gH}, V_{gL}, Vᵢₙᵢₜ, V_{dd}, V_{SS}, etc.

In the embodiment, the first conductive layer 1, the second conductive layer 3, and the first insulating layer 2 are located in different regions of the array substrate and provided for different functions. Specifically, in the pixel region, the first conductive layer 1, the second conductive layer 3, and the first insulating layer 2 may form a capacitor for image displaying of the pixel region, wherein the thickness of the portion of the first insulating layer 2 in the pixel region is not suitable to be too large. If the thickness of the portion of the first insulating layer 2 in the pixel region is increased, the distance between the first conductive layer 1 and the second conductive layer 3 will be increased, and thus a capacitance value of the capacitor is changed, thereby affecting the display by the pixel region. In addition, as there are generally many pixel units in the pixel region, the signal input lines, after entering the pixel region from the signal input region, are branched into a plurality of circuit lines in the pixel region such that current of each circuit line is lower. As the circuit lines in the pixel region may belong respectively to the first conductive layer 1 and the second conductive layer 3 of the pixel region, on which the current is lower, breakdown phenomena do not occur even if the thickness of the first insulating layer 2 were small.

In the embodiment, in the signal input region, the first conductive layer 1 and the second conductive layer 3 are mainly used for arrangement of the signal input lines, and the first insulating layer 2 between the first conductive layer 1 and the second conductive layer 3 is mainly used to isolate the first conductive layer 1 and the second conductive layer 3 to avoid short circuit. As voltage on the signal input line in the signal input region is much greater than the voltage of the circuit line in the pixel region, the thickness of the portion of the first insulating layer 2 in the signal input region is configured to be greater than the thickness of the portion of the first insulating layer 2 in the pixel region in order to avoid the breakdown of the first insulating layer 2 during the TFT aging test, ensuring the quality of the display panel.

The first conductive layer 1 described above may serve as a gate electrode of the TFT in the TFT region.

In the present embodiment, the first insulating layer 2 may be formed from silicon oxide.

In some embodiments, the array substrate includes an active layer 4 on a side of the first conductive layer 1 that faces away from the first insulating layer 2. In the embodiment, the active layer 4 may serve as a conductive channel of the TFT in the array substrate, and the active layer 4 may be made of a semiconductor material, such as an amorphous silicon material, wherein the active layer 4 may be disposed only in the pixel region rather than in the signal input region.

In some embodiments, the array substrate includes a second insulating layer 5 on a side of the active layer 4 that faces the first conductive layer 1. In the embodiment, the first conductive layer 1 and the active layer 4 can be isolated by the second insulating layer 5 to avoid short circuit between the first conductive layer 1 and the active layer 4. The second insulating layer 5 may be made of SiO₂ or silicon nitride.

In some embodiments, the array substrate includes a buffer layer 6 on a side of the active layer 4 that faces away from the first conductive layer 1. In the embodiment, the buffer layer 6 can be made of SiNₓ and SiOₓ, and the buffer layer 6 is mainly used to protect the active layer 4, thereby ensuring the display effect of the display panel.

In some embodiments, the buffer layer 6 may be disposed directly on the base substrate 7. In the present embodiment, the base substrate 7 may be a glass substrate as a substrate for forming others functional layers.

In some embodiments, the array substrate may include a planarization layer 8 on the side of the second conductive layer 3 facing away from the first conductive layer 1. In the embodiment, the planarization layer 8 is used to achieve planarization of the film layer. In addition, the planarization layer 8 may be made of an insulating material, which can reduce magnetic field interference and improve quality of the display panel.

In an embodiment, the portion of the first insulating layer 2 in the pixel region has a thickness in the range of 1000 angstroms˜2500 angstroms, or less than 1000 angstroms. The thickness of the portion of the first insulating layer 2 in the signal input region is in the range of 3000 angstroms˜8000 angstroms, or greater than 8000 angstroms.

In an embodiment, the first conductive layer 1 and the second conductive layer 3 may each be made of a metal layer.

Embodiments of the present disclosure further provide a display panel including the above array substrate.

Embodiments of the present disclosure provide a display panel, which alleviates short circuit between overlapping lines in an array substrate. In the related art, as line voltage in a signal input region of the array substrate is greater than that in a pixel region, when the array substrate is subjected to the TFT Aging test, the first insulating layer between the first conductive layer and the second conductive layer is often broken down in the signal input region, causing short circuit between the first conductive layer and the second conductive layer and affecting the quality of the array substrate. Compared with the related art, in the array substrate provided by the embodiments of the present disclosure, the thickness of the portion of the first insulating layer in the pixel region is less than the thickness of the portion of the first insulating layer in the signal input region. In this way, the thickness of the portion of the first insulating layer in the signal input region may be increased without affecting the thickness of the portion of the first insulating layer in the pixel region, so that the display effect of the pixel region can be ensured while breakdown of the first insulating layer and thus occurrence of short circuit between the first conductive layer and the second conductive layer in the signal input region can be avoided.

Embodiments of the present disclosure further provide a display apparatus, including the above array substrate.

Embodiments of the present disclosure provide a display apparatus, which may alleviate a short circuit between overlapping lines in an array substrate. In the related art, as line voltage in a signal input region of the array substrate is greater than that in a pixel region, when the array substrate is subjected to the TFT Aging test, the first insulating layer between the first conductive layer and the second conductive layer is often broken down in the signal input region, causing short circuit between the first conductive layer and the second conductive layer and affecting the quality of the array substrate. Compared with the related art, in the array substrate provided by the embodiments of the present disclosure, the thickness of the portion of the first insulating layer in the pixel region is less than the thickness of the portion of the first insulating layer in the signal input region. In this way, the thickness of the portion of the first insulating layer in the signal input region may be increased without affecting the thickness of the portion of the first insulating layer in the pixel region, so that the display effect of the pixel region can be ensured while breakdown of the first insulating layer and thus occurrence of short circuit between the first conductive layer and the second conductive layer in the signal input region can be avoided.

According to an aspect of the present disclosure, a method of manufacturing an array substrate is provided, the method including:

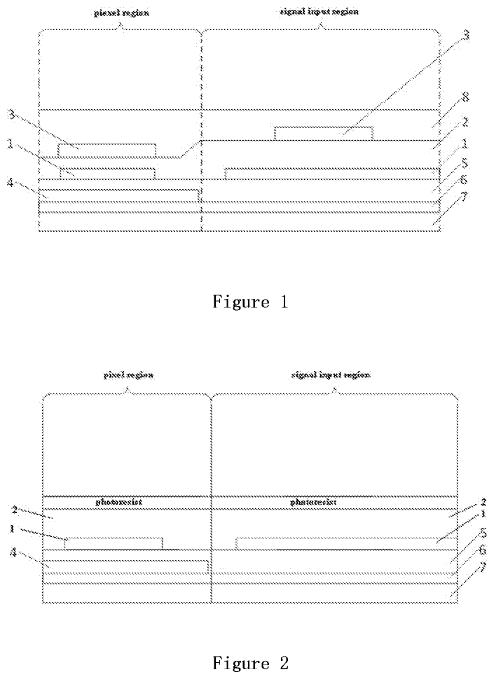

disposing a first conductive layer 1 on a base substrate 7, as shown in FIG. 2, wherein the base substrate 7 includes a pixel region and a signal input region, or in other words, the array substrate obtained includes the pixel region and the signal input region after devices are completely formed on the base substrate 7, and the pixel region substantially corresponds to a display area in the display panel, and is mainly used for controlling a luminance of the pixel unit or color of the light to display an image, and the signal input region includes some input signal lines of driving circuits for signal input, for example, V_{gH}, V_{gL}, Vᵢₙᵢₜ, V_{dd}, V_{SS}, etc.;

forming a first insulating layer 2 on a side of the first conductive layer 1 facing away from the base substrate, the first insulating layer 2 having a first predetermined thickness, which may be in the range of 3000 angstroms ˜8000 angstroms or greater than 8000 angstroms;

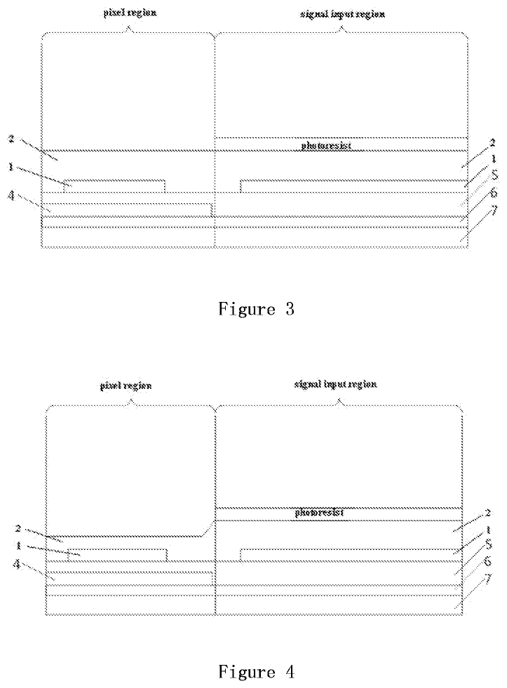

coating photoresist on a side of the first insulating layer 2 facing away from the first conductive layer 1 to form a photoresist layer, and exposing and developing the photoresist layer to remove the photoresist layer in the pixel region, as shown in FIGS. 3; and

etching the first insulating layer 2 in the pixel region to reduce the thickness of the first insulating layer 2 in the pixel region to a second predetermined thickness, which is less than the first predetermined thickness, and which may be in a range of 1000 angstroms ˜2500 angstroms or less than 1000 angstroms, as shown in FIG. 4.

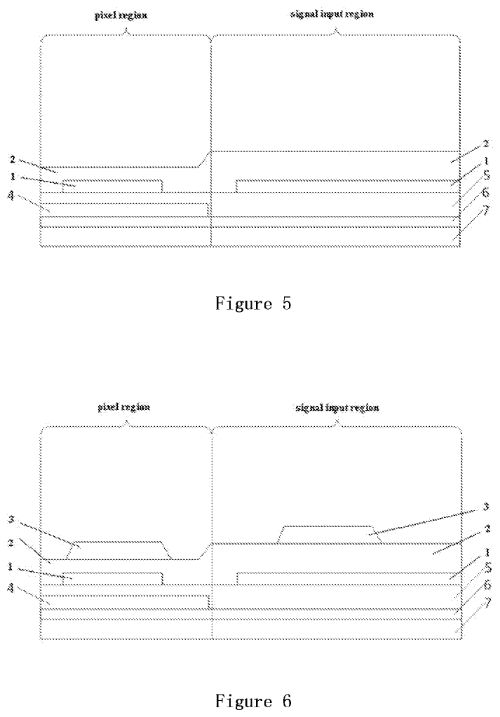

In one embodiment, the method of manufacturing the array substrate may further include: performing a stripping process to etch away the photoresist in the signal input region, as shown in FIG. 5.

In an embodiment, the method of manufacturing the array substrate may further include: simultaneously forming the second conductive layer 3 on a side of the first insulating layer 2 facing away from the first conductive layer 1, that is, simultaneously forming the second conductive layer 3 on the first insulating layer 2 having the predetermined thickness in the signal input region and on the first insulating layer 2 having the second predetermined thickness in the pixel region, as shown in FIG. 6. For example, the second conductive layer 3 is formed by depositing a metal layer and performing a patterning process on the metal layer.

In the related art, since the line voltage in the signal input region of the array substrate is greater than the line voltage in the pixel region, when the array substrate is subjected to the TFT Aging test, the first insulating layer between the first conductive layer and the second conductive layer is often broken down in the signal input region, causing short circuit between the first conductive layer and the second conductive layer, and thus affecting the quality of the array substrate. Compared with the related art, in the array substrate provided by the embodiments of the present disclosure, the thickness of the portion of the first insulating layer in the pixel region is less than the thickness of the portion of the first insulating layer in the signal input region. In this way, the thickness of the portion of the first insulating layer in the signal input region can be increased without affecting the thickness of the portion of the first insulating layer in the pixel region, thereby ensuring the display effect of the pixel region while avoiding breakdown of the first insulating layer and short circuit between the first conductive layer and the second conductive layer in the signal input region.

In the embodiment, the first conductive layer 1, the second conductive layer 3, and the first insulating layer 2 functions in different ways in different regions of the array substrate. Specifically, in the pixel region, the first conductive layer 1, the second conductive layer 3, and the first insulating layer 2 may form a capacitor for image display of the pixel region, wherein the thickness of the portion of the first insulating layer 2 in the pixel region is not suitable to be too large. If the thickness of the portion of the first insulating layer 2 in the pixel region increases, the distance between the first conductive layer 1 and the second conductive layer 3 is increased and thus the capacitance value of the capacitor is changed, which affects display effect in the pixel region. In addition, in the pixel region, as there are generally many pixel units, when the signal input lines in the signal input region enter the pixel region, they branches into a plurality of circuit lines, so that the current of each circuit line is lower. The circuit lines may be respectively in the first conductive layer 1 and the second conductive layer 3 in the pixel region, and breakdown phenomena do not occur even if the thickness of the first insulating layer 2 is small because the current of each circuit line is lower. In the signal input region, the first conductive layer 1 and the second conductive layer 3 are mainly used for arrangement of the signal input lines, and the first insulating layer 2 between the first conductive layer 1 and the second conductive layer 3 is mainly used to isolate the first conductive layer 1 and the second conductive layer 3 so as to avoid short circuit phenomenon. As the voltage of the signal input lines in the signal input region is much greater than the voltage of the circuit line in the pixel region, the thickness of the portion of the first insulating layer 2 in the signal input region may be configured to be greater than the thickness of the portion of the first insulating layer 2 in the pixel region in order to avoid breakdown of the first insulating layer 2 during a TFT aging test, ensuring the quality of the display panel. The first insulating layer may be formed of silicon oxide.

The first conductive layer 1 described above may be used as a gate electrode of the TFT in the TFT region.

In an embodiment, the method of manufacturing the array substrate may further include: providing an active layer 4 in the pixel region above the base substrate 7 before disposing the first conductive layer 1 on the side of the base substrate 7. That is, the active layer 4 is on the side of the first insulating layer 2 close to the base substrate 7. In the embodiment, the active layer 4 may serve as a conductive channel of the TFT in the array substrate, and the active layer 4 may be made of a semiconductor material, such as amorphous silicon. In the embodiment, the active layer 4 may be disposed only in the pixel region rather than in the signal input region.

In one embodiment, the method of manufacturing the array substrate may further include: before disposing the first conductive layer 1 on the side of the base substrate 7 and after providing the active layer 4 in the pixel region above the base substrate 7, providing a second insulating layer 5 on a side of the active layer facing the first conductive layer. That is, the second insulating layer 5 is on the side of the first insulating layer 2 close to the base substrate 7. In the embodiment, the first conductive layer 1 and the active layer 4 may be isolated by the second insulating layer 5, avoiding short circuit between the first conductive layer 1 and the active layer 4. The second insulating layer 5 may include SiO₂ or silicon nitride.

In one embodiment, the method of manufacturing the array substrate may further include: before providing the active layer 4 in the pixel region above the base substrate 7, providing a buffer layer 6 on the base substrate 7, which may be made of SiNₓ and SiOₓ. The buffer layer 6 is mainly used to protect the active layer 4, thereby ensuring the display effect of the display panel.

In one embodiment, the method of manufacturing the array substrate may further include: providing a planarization layer 8 on a side of the second conductive layer 3 facing away from the base substrate. In the present embodiment, the planarization layer 8 is provided for achieving planarization of the film layers. In addition, the planarization layer 8 may be made of an insulating material, so as to reduce magnetic field interference and improve the quality of the display panel.

The above is only the specific embodiments of the present disclosure, but the scope of the present disclosure is not limited thereto, and any person skilled in the art can easily think of changes or substitutions within the technical scope of the disclosure, which should be covered within the scope of protection of the present disclosure. Therefore, the scope of protection of the present disclosure should be subject to the scope of protection of the claims

1. An array substrate, comprising:
a base substrate;
a first conductive layer on a side of the base substrate;
a first insulating layer on a side of the first conductive layer facing away from the base substrate; and
a second conductive layer on a side of the first insulating layer facing away from the first conductive layer;
wherein, the base substrate includes a pixel region and a signal input region, and a thickness of a portion of the first insulating layer in the pixel region is less than a thickness of a portion of the first insulating layer in the signal input region.

2. The array substrate as claimed in claim 1, further comprising:
an active layer on a side of the first conductive layer facing away from the first insulating layer.

3. The array substrate as claimed in claim 2, further comprising:
a second insulating layer on a side of the active layer facing the first conductive layer.

4. The array substrate as claimed in claim 2, further comprising:
a buffer layer on a side of the active layer facing away from the first conductive layer.

5. The array substrate as claimed in claim 1, further comprising:
a planarization layer on a side of the second conductive layer facing away from the first conductive layer, the planarization layer covering the second conductive layer.

6. The array substrate as claimed in claim 1, wherein
the portion of the first insulating layer in the pixel region has a thickness in a range of 1,000 angstroms to 2,500 angstroms or less than 1,000 angstroms.

7. The array substrate as claimed in claim 1, wherein
the portion of the first insulating layer in the signal input region has a thickness in a range of 3,000 angstroms to 8,000 angstroms or greater than 8,000 angstroms.

8. The array substrate as claimed in claim 1, wherein
the first insulating layer is made of silicon oxide.

9. The array substrate as claimed in claim 3, wherein
the second insulating layer is made of silicon dioxide or silicon nitride.

10. A display panel comprising the array substrate as claimed in claim 1.

11. A display apparatus comprising the array substrate as claimed in claim 1.

12. A method of manufacturing an array substrate, the method comprising:
providing a first conductive layer on a base substrate, the substrate comprising a pixel region and a signal input region;
forming a first insulating layer with a first predetermined thickness on a side of the first conductive layer facing away from the substrate;
forming a photoresist layer on a side of the first insulating layer facing away from the first conductive layer, and performing exposure and development processes on the photoresist layer to remove a portion of the photoresist layer in the pixel region of the base substrate; and
etching the first insulating layer in the pixel region of the base substrate such that a thickness of a portion of the first insulating layer in the pixel region of the substrate is reduced from the first predetermined thickness to a second predetermined thickness.

13. The method of manufacturing an array substrate as claimed in claim 12, further comprising:
peeling off a portion of the photoresist layer in the signal input region and simultaneously forming a second conductive layer on portions of the first insulating layer having the first predetermined thickness in the signal input region and the portion of the first insulating layer having the second predetermined thickness in the pixel region.

14. The method of manufacturing an array substrate as claimed in claim 12, the method further comprising:
providing an active layer over a portion of the base substrate in the pixel region, before providing the first conductive layer on the base substrate.

15. The method of manufacturing an array substrate as claimed in claim 14, the method further comprising:
providing a second insulating layer on a side of the active layer facing the first conductive layer, before providing the first conductive layer on the base substrate and after providing the active layer over the portion of the base substrate in the pixel region.

16. The method of manufacturing an array substrate as claimed in claim 14, the method further comprising:
providing a buffer layer on the base substrate, before providing the active layer over the portion of the base substrate in the pixel region.

17. The method of manufacturing an array substrate as claimed in claim 13, further comprising:
providing a planarization layer on a side of the second conductive layer facing away from the base substrate.

18. The method of manufacturing an array substrate as claimed in claim 12, wherein the first insulating layer is made of silicon oxide.

19. The method of manufacturing an array substrate as claimed in claim 12, wherein the second insulating layer is made of silicon dioxide or silicon nitride.
